(19) United States
(12) Patent Application Publication
(10) Pub. No.: US 2024/0091825 A1
(43) Pub. Date: Mar. 21, 2024

(54) CLEANING APPARATUS, CLEANING METHOD, IMPRINT APPARATUS, AND METHOD FOR MANUFACTURING AN ARTICLE

(71) Applicant: CANON KABUSHIKI KAISHA, Tokyo (JP)

(72) Inventors: HIROYUKI MARUYAMA, Tochigi (JP); Tadayasu Nishikawa, Tochigi (JP)

(21) Appl. No.: 18/455,976

(22) Filed: Aug. 25, 2023

(30) Foreign Application Priority Data
Sep. 15, 2022 (JP) 2022-146977

(51) Int. Cl. B08B 7/00; G03F 7/00

(52) U.S. Cl. CPC B08B 7/0035; G03F 7/0002; G03F 7/70925

(57) ABSTRACT

[Problem] The provision of a cleaning apparatus that is useful in the cleaning of an original plate that is used when forming a pattern on top of a substrate. [Means for solving the problem] A cleaning apparatus configured to clean an original plate that is used when forming a pattern in an imprint material on top of a substrate; wherein the cleaning apparatus comprises an irradiating unit configured to release plasma onto a first side of the original plate; and a heating unit configured to radiate heat onto a second side of the original plate, and heat the original plate; and wherein the irradiating unit and the heating unit are disposed such that the original plate is interposed between the irradiating unit and the heating unit.

### BACKGROUND OF THE INVENTION

### Field of the Invention

The present invention relates to a cleaning apparatus, a cleaning method, an imprint apparatus, and a manufacturing method for an article.

### Description of the Related Art

As the demand for the refinement of semiconductor devices continues, in addition to conventional photolithographic technologies, micro fabrication technologies in which uncured resin (an imprint material) is cast on top of a substrate using a mold (a template), and a resin pattern is formed on top of the substrate are gaining attention. The associated technology is also called imprint technology, and is able to form microstructures in nanometer order on a substrate.

As one example of an imprint technology, there is, for example, a photo-curing method. In an imprint apparatus that uses a photo-curing method, first resin is supplied (applied) to a shot region (an imprint region) on top of a substrate. Next, the resin is cured by irradiating a light in a state in which the uncured resin on top of the substrate has been contacted with a mold, and a pattern is formed on top of the substrate by separating the mold from the cured resin.

In imprint apparatuses, due to the mold being contacted with the resin on top of the substrate, there are cases in which a cured substance from the resin remains on the mold. If the imprint processing is performed in a state in which a cured substance from the resin remains on the mold, the remaining resin will be transferred as is, and imperfections (flaws and the like) will occur in the pattern that is formed on the substrate. Thus, it is necessary to periodically clean the mold.

Such cleaning technologies for molds are proposed in Japanese Unexamined Patent Application, First Publication No. 2009-16434, Japanese Unexamined Patent Application, First Publication No. 2010-93245, and Published Japanese Translation No. 2021-506119 of the PCT International Publication. Japanese Unexamined Patent Application, First Publication No. 2009-16434 discloses a technology that eliminates foreign substances using plasma. Japanese Unexamined Patent Application, First Publication No. 2010-93245, discloses a technology in which a cleaning apparatus that cleans a member to be cleaned using plasma is provided inside of an exposure apparatus. Japanese Unexamined Patent Application, First Publication No. 2021-506119 discloses a technology in which an exhaust opening unit, a heat radiating opening unit of a heater, an opening unit for plasma irradiation, and a gas release opening unit are lined up and disposed around the center of a plasma head, and foreign substances that have become attached to a substrate due to the plasma head are eliminated.

However, in the prior cleaning apparatuses such as those that have been described above, the positions of the substrate heating unit and the plasma radiating unit are different. Therefore, in a case in which the substrate is heated while the substrate or the plasma radiating unit are moved, there is a problem in which after heating the substrate, it takes time to reach the plasma radiating unit, and the temperature of the substrate heating unit decreases.

### SUMMARY OF THE INVENTION

In this context, the goal of the present invention is the provision of a cleaning apparatus that is useful in the cleaning of an original plate that is used when forming a pattern on a substrate.

As one aspect of the present invention there is an imprint method, and as another aspect of the present invention there is a cleaning apparatus, wherein the cleaning apparatus cleans original plates used when forming a pattern in an imprint material on top of a substrate, and the cleaning apparatus is provided with an irradiating unit that releases plasma onto a first side of the original plate, and a heating unit that radiates heat onto a second side of the original plate and heats the original plate, wherein the heating unit and the irradiating unit are disposed such that the original plate is interposed between the heating unit and the irradiating unit.

Further features of the present invention will become apparent from the following description of exemplary embodiments with reference to the attached drawings.

### BRIEF DESCRIPTION OF THE DRAWINGS

FIG. 1 is a schematic side view diagram showing a configuration of a cleaning apparatus according to a First Embodiment.

FIG. 2 is a schematic overhead view diagram of the cleaning apparatus of FIG. 1

FIG. 3 is a flowchart showing cleaning processing according to the First Embodiment.

FIG. 4 is a schematic side view diagram of a configuration of a cleaning apparatus according to a Second Embodiment.

FIG. 5 is a schematic side view diagram of a configuration of a cleaning apparatus according to a Third Embodiment.

FIG. 6 is a schematic diagram showing a configuration of an imprint apparatus to which a cleaning apparatus has been applied.

FIG. 7A to FIG. 7F are a schematic diagram for explaining a manufacturing method for an article.

### DESCRIPTION OF THE EMBODIMENTS

Below, optimal modes for implementing the present invention will be explained using Examples and Figures with reference to the attached drawings. Note that in each Figure, the same reference numerals are attached to the same members and elements, and redundant descriptions will be omitted or simplified.

In the following Examples, examples are explained in which the present invention is applied to an original plate (a mold) that is used in an imprint apparatus that forms a pattern in an imprint material on top of a substrate. However, the present invention is not limited to use in imprint apparatuses, and may also be applied to, for example, a mask (original plate) that is used in an exposure apparatus that projects and transfers a pattern onto a substrate. In this manner, the original plate in the present invention includes molds that are used in imprint apparatuses and masks that are used in exposure apparatuses.

In addition, a control or drive relating to a θ X axis, a θ Y axis, or a θ Z axis each refer to a control or drive in relation to rotation around an axis that is parallel to the X axis, rotation around an axis that is parallel to the Y axis, and rotation around an axis that is parallel to the Z axis. In addition, a position is information that can be defined based on coordinates on the X axis, the Y axis, and the Z axis, and a posture is information that can be defined based on a value of the θ X axis, the θ Y axis, and the θ Z axis. Positioning refers to controlling the position and/or posture. Aligning can include controlling the position and/or posture of at least one of a substrate 202 and a mold 1.

### First Embodiment

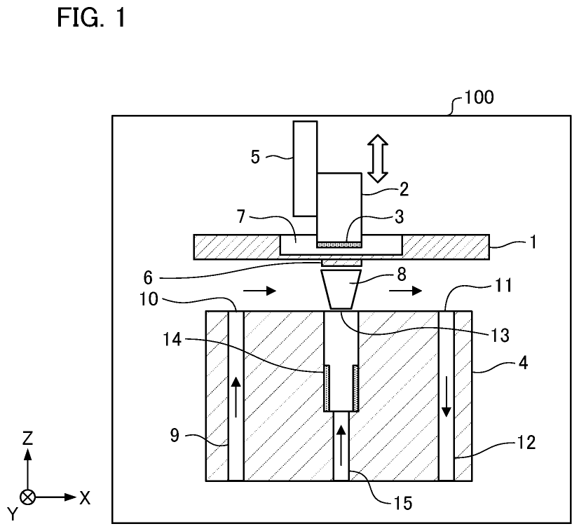

FIG. 1 is a schematic diagram showing a configuration of a cleaning apparatus 100 according to the Present Embodiment. Below, the cleaning apparatus 100 according to the Present Embodiment will be explained with reference to FIG. 1. In addition, in the Figures below, an explanation will be given in which an X axis and Y axis are provided that are orthogonal to each other on a plane that is parallel to a surface of the mold 1, and a Z axis is provided in a direction that is orthogonal to the X axis and the Y axis.

The cleaning apparatus 100 is provided with a mold stage (not shown), a heating unit 2, a plasma head 4, a drive mechanism 5, and a control unit (not show).

The mold (original plate) 1 is, for example, used in an imprint apparatus that forms a pattern in an imprint material on top of a substrate. The mold 1 is held by the mold stage. The mold stage holds the mold 1 by, for example, a vacuum sucking force or an electrostatic force.

The surface of one side (a first side) of the mold 1 is provided with a pattern unit 6 on which a pattern of protrusions and recessions has been 3-dimesnionally formed that will be formed in the imprint material that has been supplied on top of the substrate. The pattern unit 6 is also called a mesa, and is formed on a protruding part of several dozen to several hundred μm such that no other parts of the mold 1 aside from the pattern unit 6 contact the substrate. Due to this, it is easy for cured substances from the imprint material to remain on an edge of the pattern unit 6 that is called the mesa edge, and there are cases in which when imprinting processing is repeatedly performed, the cured substance from the imprint material accumulates.

A core out unit 7 (a cavity unit) in which a cylindrical shape has been carved out is formed on the central portion of the other side (a second side) of the mold 1 in the First Embodiment. The core out unit 7 is formed on a region that corresponds to the protrusions and recessions of the pattern unit 6. More specifically, the core out unit 7 is a cavity having an area that is wider than the area of the protrusions and recessions of the pattern unit 6.

The heating unit 2 heats the mold 1 by radiating heat onto the other side of the mold 1. The heating unit 2 is held by the drive mechanism 5, which will be explained below. Note that the mold 1 is interposed by the heating unit 2, and the heating unit 2 is disposed on top of the pattern unit 6 that is formed on the first surface, which is the opposite side in the direction of the Z axis of the second side of the mold 1, and therefore, when heating the mold 1, it is possible to efficiently heat the pattern unit 6 of the mold 1 and the surroundings of the pattern unit 6. The heating unit 2 is configured so as to have a heat radiating unit 3.

The heat radiating unit 3 is provided with a mechanism that radiates heat, and is configured by, for example, a far infrared heater. However, the heat radiating unit 3 is not limited thereto, and any mechanism or apparatus may also be used if it is able to radiate heat. In this context, in an imprint apparatus that uses a photocuring method, quartz is used as the material for the mold 1. A mold 1 that uses quartz has a transmittance of 90% or greater for wavelengths from 0.2 μm to 2 μm. The transmittance for quartz is low in the far infrared radiation region, which is a wavelength of 3 μm or more, and it becomes easy for it to absorb heat. The heat radiating unit 3 in the First Embodiment is configured by a far infrared heater and therefore, it is possible to efficiently heat the mold 1.

Note that heat radiating unit 3 in the First Embodiment is configured at a size in which the outer circumference of the heat radiating unit does not exceed the outer circumference of the heating unit 2. That is, the outer circumference of the heat radiating unit 3 is configured so as to be the same size as the outer circumference of the heating unit 2, or to be smaller than the outer circumference of the heating unit 2. Note that although any outer circumference is acceptable as long as the outer circumference of the heat radiating unit 3 does not exceed the outer circumference of the heating unit 2, in order to efficiently heat the entirety of the pattern unit 6, it is preferable if the outer circumference of the heat radiating unit 3 is configured so as to have the same area as the area of the pattern unit 6, or to have a larger area than the area of the pattern unit 6. Note that the outer circumferences of the heating unit 2 and the heat radiating unit 3 are configured so as to be smaller than the inner circumference of the core out unit 7. That is, the heating unit 2 and the heat radiating unit 3 are configured so as to be smaller than the shape of the cavity of the core out unit 7.

The plasma head 4 is a cleaning unit (a cleansing apparatus) that performs cleaning of the mold 1 in a state in which the mold 1 is held by the mold stage based on predetermined cleaning conditions that have been set in advance. The plasma head 4 is configured so as to include a gas flow path 9, a gas release opening unit 10, a gas exhaust release opening unit 11, a gas flow path 12, a plasma irradiating unit 13, an electrode 14, and a gas flow path 15.

The gas flow path 9 is a flow path for releasing an inert gas such as a purge gas to the outside of the plasma head 4. The gas release opening unit 10 functions as a supply port that supplies purge gas in the vicinity of the plasma irradiating unit 13 when the purge gas is released outside of the plasma head 4. The gas exhaust release opening unit 11 functions as an exhaust port for collecting the released purge gas and surrounding gas including a first gas and a second gas that will be explained below. The gas flow path 12 is a flow path for the purge gas that has been collected from the gas release opening unit 10.

The plasma irradiating unit 13 irradiates (releases) plasma 8. The electrode 14 is inside of the plasma irradiating unit 13, and the plasma 8 is generated by applying a high frequency voltage to this electrode 14. The plasma 8 that has been generated is irradiated to the outside of the plasma head 4 by the plasma irradiating unit 13. The electrode 14 may be a parallel flat board-type structure covered by a dielectric, or a torch-type cylindrical structure. However, it is not limited thereto, and may be any structure as long as it is a structure that generates the plasma 8. The gas flow path 15 is a flow path for providing a first gas for generating the plasma 8, and a second gas comprising a reaction substance to the plasma irradiating unit 13. The first gas and the second gas pass through the gas flow path 12 from the gas exhaust release opening 11 and are collected. Note that in the First Embodiment, there is one plasma irradiating unit 13 that irradiates the plasma 8 provided to the plasma head 4. However, the present invention is not limited thereto, and a plurality of plasma irradiating units 13 may be provided to the plasma head 4.

The plasma head 4 is disposed so as to oppose the mold 1. Specifically, this is disposed such that the plasma irradiating unit 13 of the plasma head 4 opposes the pattern unit 6 of the mold 1. Therefore, in the First Embodiment, both the heat radiating unit 3 of the heating unit 2 and the plasma irradiating unit 13 of the plasma head 4 are disposed so that the mold 1 is interposed therebetween.

It is possible to arbitrarily set the position in which the plasma head 4 is disposed, and to arbitrarily set the interval between the plasma head 4 and the pattern unit 6 in the Z axis direction. In this context, when the plasma irradiating unit 13 has irradiated the plasma 8, it is preferrable if the plasma head 4 is disposed in a position or an interval at which it can irradiate the entire area on which the pattern of the pattern unit 6 is formed. Note that it is more preferable if when the plasma irradiating unit 13 has irradiated the plasma 8, the plasma head 4 is disposed in a position in which it is also possible to irradiate the plasma 8 in the surroundings of the pattern unit 6 including the pattern unit 6 itself. By setting this kind of disposed position, when the plasma 8 has been irradiated from the plasma irradiating unit 13, it is possible to appropriately irradiate the plasma 8 even in the surroundings including the edge of the pattern unit 6, and it is possible to clean the foreign substances that remain on the pattern unit 6 and the edge of the pattern unit 6.

Note that the plasma 8 that is irradiated from the plasma head 4 is, for example, atmospheric pressure plasma that is created in atmospheric pressure using a high frequency power supply. By using atmospheric pressure plasma, it becomes possible to lower the cost of the invention. In the case in which the plasma 8 is surrounded by atmosphere, various gas phase reactions will occur, and irregularities will occur in the cleaning of the pattern unit 6. In order to inhibit the occurrence of these irregularities, it is preferable to purge the surroundings of the plasma 8 using an inert gas such as a purge gas or the like. Therefore, in the First Embodiment, when the plasma 8 is irradiated from the plasma irradiating unit 13 of the plasma head 4, purge gas is released from the gas release opening unit 10.

Purge gas travels through the gas flow path 9 and is released from the gas release opening 10 as is described above. The purge gas that has been released flows over the upper surface of the plasma head 4, travels along the plasma radiating unit 13, passes through the gas flow path 12 from the gas exhaust release opening 11, and is collected. Note that gasses such as the purge gas or the first gas, the second gas, or the like may also be collected and processed using an elimination apparatus (a collection apparatus) that is not shown.

The drive mechanism 5 (a first drive unit) holds and moves the heating unit 2. In the First Embodiment, the drive mechanism 5 is configured to be able to move the heating unit 2 in the direction of the Z axis in relation to the mold 1, and can perform driving such that the lower surface (the surface that corresponds to the base of the core out unit 7) of the heat radiating unit 3 approaches the base of the core out unit 7. Note that the drive mechanism 5 is not limited to only performing drive in the Z axis direction, and may also be configured so as the be able to perform drive in the X axis direction and the Y axis direction.

The control unit (not shown) includes a CPU, a memory (a storage unit), or the like, is configured of at least one computer, and is connected to each of the configurational elements of the cleaning apparatus 100 by a circuit. In addition, the control unit integrally controls the operation adjustments and the like of each of the configurational elements of the entirety of the cleaning apparatus according to a program that has been stored on a memory. In addition, the control unit may also be configured together (inside of a shared body) with another of the units of the cleaning apparatus 100. Furthermore, the control unit, may also be configured separately (inside of a different body) from the other units of the cleaning apparatus 100, and it may also be disposed in a separate location from and remotely control the cleaning apparatus 100.

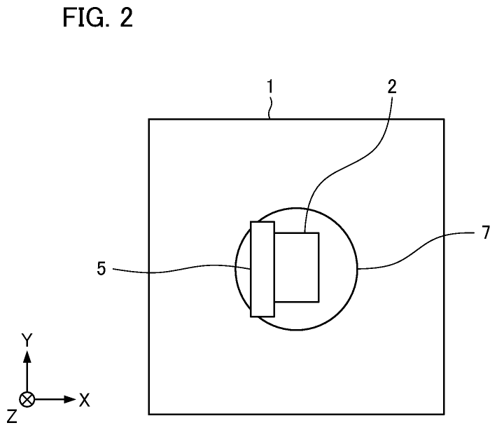

FIG. 2 is a schematic overhead view diagram of the cleaning apparatus 100 that is shown in FIG. 2. The heating unit 2 is disposed in approximately the center of the core out unit 7 of the mold 1. That is, the heating unit 2 is disposed in the cleaning apparatus 100 while being held by the drive mechanism 5 such that the approximate center position of the heating unit 2 and the approximate center position of the core out unit 7 align in the Z axis direction. Note that the cleaning apparatus 100 in the First Embodiment may also be provided with a measuring apparatus (not shown) that measures the position and state of the mold 1 and the core out unit 7.

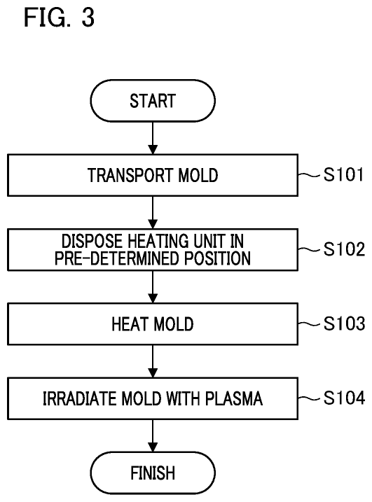

FIG. 3 is a flowchart showing an example of the cleaning processing according to the First Embodiment. The cleaning processing for the cleaning apparatus 100 in the First Embodiment will be explained below with reference to FIG. 3. Note that each operation (processing) shown in the flowchart in FIG. 3 is controlled by the control unit executing a computer program.

First, during step S101, the control unit controls a transport mechanism, which is not shown, transports the mold 1 inside of the cleaning apparatus 100, and loads it onto a mold stage (a transport process). When loading the mold 1 onto the mold stage, the control unit moves the heating unit 2 upwards in the direction of the Z axis using the drive mechanism 5, and evacuates it so that this does not contact the mold 1.

Next, during step S102, after loading the mold 1 onto the mold stage, the control unit controls the drive mechanism 5 and moves the heating unit 2 downwards in the direction of the Z axis from the position to which it was evacuated during step S101 (a movement process). When this downward movement occurs, the control unit disposes the heat radiating unit 3 of the heating unit 2 so that it is in a position that is close to the base of the core out unit 7. In this context, when the heat radiating unit 3 is disposed in a position that is close to the base of the core out unit 7, the distance (interval) in the Z axis direction between the lower surface of the heat radiating unit 3 and the base of the core out unit 7 can be determined by the control unit controlling the drive mechanism 5. Note that although it is possible to arbitrarily set the distance (interval) in the Z axis direction between the lower surface of the heat radiating unit 3 and the base of the core out unit 7, it is preferable if this distance is between 0.1 mm to 2 mm. Note that it is preferable if the heat radiating unit 3 is configured such that its size is the same as the area of the pattern unit 6, or so as to be larger than the area of the pattern unit 6.

Next, during step S103, the control unit controls the heating unit 2 and heats the mold 1 by radiating heat onto the mold 1 from the heat radiating unit 3 of the heating unit 2 (a heating process). In this context, during step S102, the lower surface of the heat radiating unit 3 is disposed in a position that is close to the base of the core out unit 7. Therefore, when the mold 1 is heated, it is possible to efficiently heat the pattern unit 6 and the vicinity of the pattern unit 6, which is supplied on the opposite side in the Z axis direction of the base of the core out unit 7.

Next, during step S104, the control unit controls the plasma head 4, irradiates the plasma 8 onto the pattern unit 6 and the vicinity of the pattern unit 6, and performs cleaning of the mold 1 (a cleaning process). In this context, the radicals that are generated in the plasma 8 that is irradiated from the plasma head 4 of the cleaning apparatus 100 in the First Embodiment are able to increase the velocity of the chemical reaction by raising the temperature of the pattern unit 6. In the First Embodiment, during step S103, the mold 1 is heated in a position that is close to the base of the core out unit 7 that is on the opposite side in the Z axis direction of the pattern unit 6 of the mold 1. Thus, the temperature of the pattern unit 6 can be efficiently raised, and therefore as has been explained above, the velocity of the chemical reaction is increased, and it is possible to increase the efficiency of the cleaning of the pattern unit 6.

In this context, in order to prevent the particles that are included in the gas caused by the chemical reaction of the plasma 8 from re-adhering to the pattern unit 6, it is preferable to keep the pattern unit 6 at a high temperature. Therefore, it is preferable that the heating unit 2 continues to heat the mold 1 until the cleaning of the mold 1 during step S104 is completed, and it is preferable if step 103 is completed in joint operation with or at the timing at which step S104 is completed. However, it is not limited thereto, and the heating of the mold 1 may also be completed before the completion of step S104, before step S104 begins, or at the same time that step S104 begins.

By performing the processing from step S101 to S104 that were described above, it is possible to appropriately clean foreign substances such as cured substances from the imprint material and the like that are adhered to the pattern unit 6 of the mold 1, the edge of the pattern unit 6, or the like.

As has been explained above, according to the cleaning apparatus 100 in the First Embodiment, it is possible to irradiate the plasma 8 onto the pattern unit 6 while keeping the pattern unit 6 at a high temperature, and it becomes possible to efficiently eliminate foreign substances such as the imprint material or the like that have accumulated on the mold 1.

### Second Embodiment

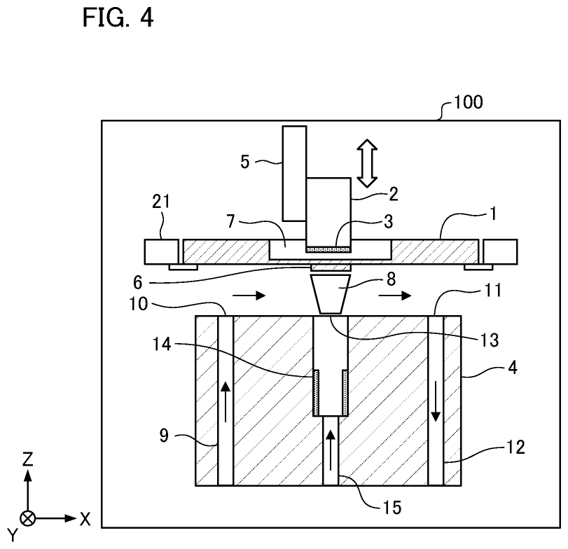

Next, the cleaning apparatus 100 according to the Second Embodiment will be explained. Note that matters that are not mentioned in the Second Embodiment follow the First Embodiment. FIG. 4 is a schematic diagram showing a configuration of the cleaning apparatus 100 according to the Second Embodiment.

In the cleaning apparatus 100 in the Second Embodiment, both a mold stage 21 and the plasma head 4 are configured so as to each be provided with a drive mechanism (not shown). The drive mechanism for the mold stage 21 (a third driving unit) is configured to be able to move the mold 1 in the direction of each axis in relation to the plasma head 4. The drive mechanism for the plasma head 4 (the second drive unit) is configured to be able to move the plasma head 4 in the direction of each axis in the relation to the mold 1. Note that the apparatus configuration other than these mechanisms is the same as the apparatus configuration in the First Embodiment, and therefore, an explanation thereof will be omitted.

In a case in which the scope of the plasma that has been irradiated onto the mold 1 is narrow in relation to the region of the pattern unit 6, or the like, it is possible to clean the entirety of the pattern unit 6 by moving either the mold stage 21 on which the mold 1 is held, or the plasma head 4 on top of the XY plane.

In addition, the cleaning apparatus 100 in the Second Embodiment may also have a detection mechanism (not shown) or the like that detects the contaminated state of the pattern unit 6 due to the adherence of foreign materials thereto. In this case, this detection mechanism detects the contaminated state of the pattern unit 6 due to the adherence of foreign substances thereto, and the mold stage 21 or the plasma head 4 may be driven by changing their movement velocity and movement range in accordance with the detected contamination state. The movement on the XY plane may be movement on just one axis, or it may also be movement on two axes. In addition, the invention may also be made such that the cleaning time is shortened by performing cleaning in only the areas in which foreign substances have adhered to the pattern unit 6 according to the contaminated state that was detected by the detection mechanism.

The heating unit 2 that is held by the drive mechanism 5 may also be driven in the Z axis direction in alignment with the driving of the mold stage 21 such that it does not contact the side surface of the core out unit 7. In addition, the drive mechanism 5 may also move this in alignment within the XY plane by aligning it with the drive of the mold stage 21. In addition, the cleaning of the entirety of the pattern unit 6 may also be performed by moving the mold stage 21 and the plasma head 4 relative to each other in the XY plane.

In this manner, according to the cleaning apparatus 100 of the Second Embodiment, it is possible to efficiently remove foreign substances such as imprint material and the like that have accumulated on the mold 1 even in cases such as when the irradiation range for the plasma 8 is narrow in relation to the pattern unit 6.

### Third Embodiment

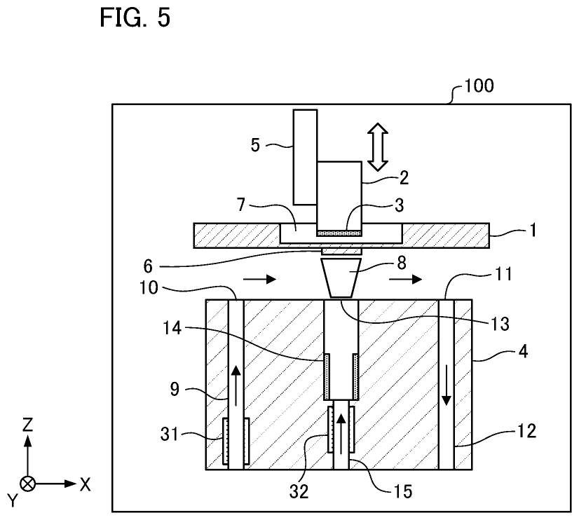

Next, the cleaning apparatus 100 in the Third Embodiment will be explained. Note that matters that are not mentioned as part of the Third Embodiment follow the First Embodiment and the Second Embodiment. FIG. 5 is a schematic side-view diagram showing a configuration of the cleaning apparatus 100 according to the Third Embodiment.

The cleaning apparatus 100 according to the Third Embodiment is configured so as to be provided with a heating mechanism 31 that heats the purge gas in the gas flow path 9 for the purge gas inside of the plasma head 4. In addition, it is also configured so as to be provided with a heating mechanism 32 that heats the gas for generating the plasma 8 inside of the gas flow path 15 for generating the plasma 8 inside of the plasma head 4. Note that the apparatus configuration is the same as the apparatus configuration for the First Embodiment aside from these mechanisms, and therefore an explanation thereof will be omitted.

The cleaning apparatus 100 may be provided with only one of the heating mechanism 31 or the heating mechanism 32, or it may also be provided with both. By heating either the purge gas or the gas for generating the plasma with this heating mechanism, or by heating them both, it is possible to increase the velocity of the chemical reaction of the radicals that are generated inside of the plasma 8, and to increase the efficiency of the cleaning of the pattern unit 6.

Note that although in the Third Embodiment the heating mechanism 31 and the heating mechanism 32 are both disposed inside of the plasma head 4, they may also be provided inside a supply path that is connected to the plasma head 4. In addition, they may also be provided both inside the supply paths and inside the plasma head 4.

In the above-describe manner, according to the cleaning apparatus 100 of the Third Embodiment, it is possible to increase the reaction velocity for the radicals that are generated inside of the plasma 8, and to efficiently eliminate foreign substances such as the imprint material and the like that have accumulated on the mold 1.

### Fourth Embodiment

Next, the cleaning apparatus 100 according to the Fourth Embodiment will be explained. In the Fourth Embodiment, the cleaning apparatus 100 is provided inside of an imprint apparatus 200. Although an explanation is given of an example in which the present invention is applied to an imprint apparatus as one example of the Fourth Embodiment, the present invention can also be applied to lithographic equipment such as, for example, an exposure apparatus that exposes a substrate, a drafting apparatus, or the like.

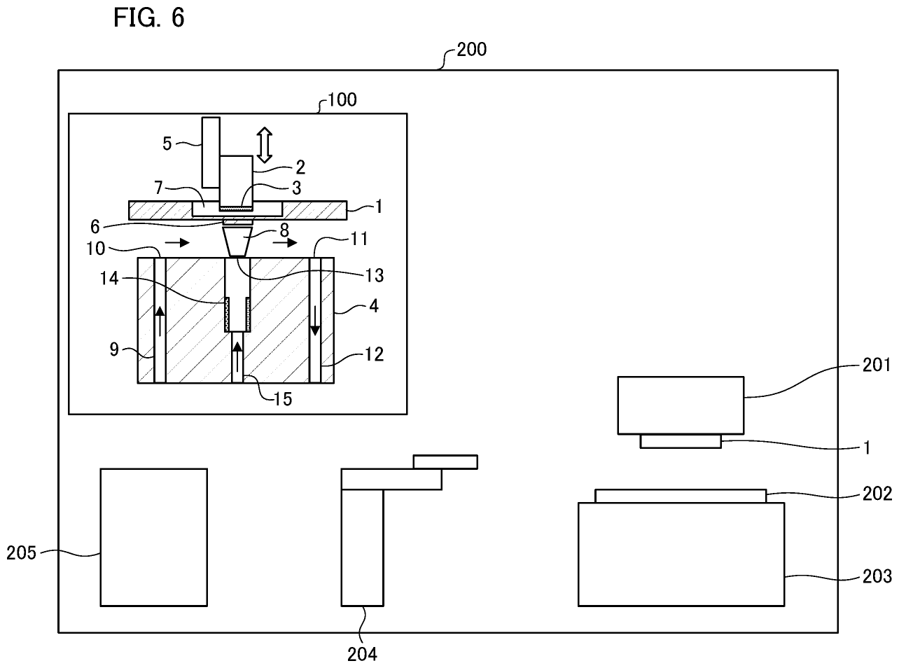

FIG. 6 is a schematic diagram showing a configuration of an imprint apparatus 200 to which the cleaning apparatus 100 has been applied. The imprint apparatus 200 is an apparatus that forms a pattern in an imprint material on top of a substrate 202 to be processed, by transferring a pattern of the mold 1 onto an imprint material on top of the substrate 202 is to be processed, using imprint processing. The imprint apparatus 200 is used in the manufacture of devices such as semiconductor devices or the like. Note that in this context the imprint apparatus is made an imprint apparatus in which a photocuring method is used.

Imprint processing (an imprint process) refers to the series of processes in which an imprint material is contacted with the pattern unit 6 of the mold 1 (a contact process), the imprint material is cured after this contact (a curing process), and in addition, after this curing, the imprint material is removed from the mold 1 (a separation process). This imprint processing is performed for each imprint region (pattern formation regions) on which a pattern will be formed on top of the substrate 202.

The substrate 202 is, for example, a single crystal silicone substrate, or an SOI (Silicon on Insulator) substrate, and this surface to be processed is coved with an imprint material in which a pattern will be formed by the pattern unit 6 that has been formed on the mold 1. In addition, the substrate 202 may also be each type of substrate such as a gallium arsenide wafer, a composite adhesive wafer, a glass wafer including quartz as the material, a crystal panel substrate, a reticle, or the like. In addition, the external shape of the substrate may also be a square or the like, not just a circle.

The imprint material uses a curing composition (sometimes called uncured resin) that is cured by the application of curing energy. Electro-magnetic waves, heat, or the like are used as the curing energy. As the electro-magnetic waves, there is, for example, light such as infrared light, visible light, ultraviolet light, or the like that is selected from the range in which the wavelengths are greater than or equal to 150 nm, and equal to or less than 1 mm. The viscosity of the imprint material (the viscosity at 25° C.) is, for example, at or above 1 mpa/s or at or below 100 mpa/s. The application amount for the imprint material (the provided amount) can specifically be adjusted in the range of 0.1 to 10 pL/drop, and normally, there are cases in which about 1 pL/drop is used. Note that the entire application amount for the imprint material is determined by the density of the pattern unit 6 and the desired remainder coating thickness.

The curing composition is a composition that is cured by the irradiation of light or by heat. From among these, curing compositions that are cured by light include at least a polymerizable composition and a photopolymerization initiator, and may also include a non-polymerizable composition or a solvent according to necessity. The non-polymerizable composition is at least one variety selected from the group of a sensitizer, a hydrogen donor, an internal mold release agent, a surfactant, an antioxidant, a polymer component, or the like. In addition, in a case in which a photo curing composition (photocurable resin) is used, the imprint material is cured using a photocuring method, and in the case in which a thermo-curable composition (a thermo-curable resin), which is a composition that is cured using heat, is used, a thermo-curing method is used to cure the imprint material.

The imprint apparatus 200 in the Fourth Embodiment is provided with a mold holding unit 201, a substrate stage 203, a transport unit 204, a collection unit 205, and the cleaning apparatus 100. In addition, it also has a control unit, an irradiating unit, an dispenser, and an alignment measuring unit, none of which are shown.

The mold holding unit 201 has a drive mechanism that moves the mold 1 while holding it. The mold holding unit 201 is able to hold the mold 1 by attracting the outer circumference region of the irradiation surface for the irradiation light of the mold 1 using a vacuum sucking force or an electrostatic force. The mold holding unit 201 moves the mold 1 in each axial direction such that the pressing of the mold 1 onto the imprint material on top of the substrate 202, and the removal of the mold 1 are selectively performed. In addition, in order to achieve high-precision positioning of the mold 1, this may also be configured from a plurality of drive systems such as a coarse movement drive system, a fine movement drive system, and the like. Furthermore, configurations are also possible that have a position adjustment function in not just the Z axis direction, but also the X axis direction and the Y axis direction, or the 0 direction of each axis, a tilt function for correcting the slope of the mold 1, or the like.

The substrate stage 203 has a stage drive mechanism that is able to move in each axial direction. In addition, the substrate stage 203 holds the substrate 202, and performs alignment of the mold 1 and the imprint region at the time of the pressing of the mold 1 onto the imprint material on top of the substrate 202. The alignment is performed by measuring a mark (an alignment mark) for the mold 1 and a mark for the substrate 202 using the alignment measuring unit that is not shown, and moving the substrate stage 203 using the stage drive mechanism based on the measurement result. The stage drive mechanism may also be configured from a plurality of drive systems such as a coarse movement driving system and a fine movement driving system in relation to each axial direction of the X axis and the Y axis. Furthermore, this may also be a configuration that has a drive system for the position adjustment in the Z axis direction, a position adjustment function in the 0 direction of the substrate 202, a tilt function for correcting the slope of the substrate 202, or the like.

After cleaning has been completed, the transport unit 204 transports the mold 1 from the cleaning apparatus to a storage location inside of the imprinting apparatus or to the mold holding unit 201. In addition, the transport unit 204 may also transport the mold 1 from outside of the imprint apparatus 200 to inside of the imprint apparatus 200.

The collection unit 205 collects the gas that is caused by performing the cleaning of the mold 1 by the cleaning apparatus 1, in particular gas that would hinder the imprint processing. However, in a case in which no gas is created that would hinder the imprint processing, or cases in which the cleaning apparatus 100 is used in a form that is independent from the imprint apparatus 200 and the like, the collection unit 205 may also not be disposed inside of the imprint apparatus 200. In this case, for example, the collection unit 205 may be disposed outside of the imprint apparatus 200.

The control unit includes a CPU, a memory (a storage unit), or the like, is configured of at least one computer, and is connected to each of the configuration elements of the imprint apparatus 200 by a circuit. In addition, the control unit integrally controls the operations, adjustments, and the like of each of the configurational elements of the entirety of the imprint apparatus 200 according to a program that has been stored on a memory. In addition, the control unit may also be configured together (inside of the same body) with another unit of the imprint apparatus 200. Furthermore, the control unit may also be configured separately (inside of a different body) from the other units of the imprint apparatus 200, and it may also be disposed in a separate location from and remotely control the imprint apparatus 200.

The irradiating unit (illuminating unit) can be provided with an irradiating optical system comprising optical elements such as a light source, a reflecting unit, and the like. The light source can irradiate an irradiation light with a wavelength that can cure the imprint material. The irradiation light that has been irradiated from the light source is irradiated onto the imprint material on top of the substrate 202 via the mold 1. As the irradiating light, there is for example, lights such as ultraviolet lights, and the like. The above-described optical elements are not limited to a reflection unit and can include a light source, and lenses or shielding plates and the like to serve as optical elements for appropriately adjusting the state of the irradiation light from the light source during the imprint processing, for example adjusting the intensity distribution, the illumination region, and the like of the light. The irradiating unit may also be disposed inside of the imprint apparatus 200. However, it is not limited thereto and the irradiating unit may also be disposed outside of the imprint apparatus 200.

The dispenser (supply unit) can be disposed in the vicinity of the mold holding unit 201. In addition, the dispenser applies the imprint material as droplets onto at least one imprint region that exists on the substrate 202. The application, application position, and application amount, and the like of the imprint material are controlled based on an operation command from the control unit. The dispenser may be disposed inside of the imprint unit 200. However, the location is not limited thereto, and the dispenser may also be disposed outside of the imprint apparatus 200.

The configuration of the cleaning apparatus 100 is the same as the configuration of the above-described First Embodiment, and therefore an explanation thereof will be omitted. In the Fourth Embodiment, after the mold 1 is cleaned using the cleaning apparatus 100, the above-described imprint processing is performed, and a pattern is formed on the imprint material on top of the substrate 202. Note that the configuration of the cleaning apparatus 100 in the Fourth Embodiment is not limited to the configuration of the First Embodiment, and may also be made the configuration of the Second Embodiment or the Third Embodiment, or may also be made a configuration that combines the configurations of the First to Third Embodiments. In addition, if it is possible to store a plurality of molds 1 inside of the imprint apparatus 200, the mold cleaning may also be performed parallelly, and the imprint processing may be performed using a different mold.

As has been explained above, in the Fourth Embodiment, by supplying the cleaning apparatus 100 inside of the imprint apparatus 200, the transport distance for the mold 1 is shorted, and therefore, it becomes possible to reduce the cleaning processing time.

### (Embodiment of a Method for Manufacturing an Article)

The method for manufacturing an article according to the Present Embodiment is ideal for, for example, the manufacturing of microdevices such as semiconductors and the like, or articles such as elements and the like that have micro-structures. The manufacturing method for an article of the Present Embodiment comprises a process in which a pattern is formed using the above-described imprint apparatus 200 on a composition that has been applied to a substrate (a process in which processing is performed on a substrate), and a process in which the substrate on which the pattern was formed using this process is treated. Furthermore, this manufacturing method also comprises other well-known processes (oxidization, film deposition, vapor deposition, topping, planarizing, etching, composition stripping, dicing, bonding, packaging, and the like). The manufacturing method for an article of the Present Embodiment is beneficial in comparison to prior methods in at least one of the function, quality, productivity, or production cost of the article. Note that in the manufacturing method for an article of the Present Embodiment, a cleaning process is executed that cleans the mold (the original plate) using the above-described cleaning apparatus 100 before the process for forming the pattern using the above-described imprint apparatus 200 is executed.

The pattern that is formed from the curing material using the imprint apparatus 200 is used either permanently in at least a portion of each type of article, or is used temporarily in the manufacturing of each type of article. The article is an electric circuit element, an optical element, a MEMS, a storage element, a sensor, a mold, or the like. As examples of the electric circuit element, there are volatile or non-volatile semiconductor memories such as DRAMs, SRAMs, flash memories, or MRAMs, and semiconductor elements such as LSIs, CCDs, image sensors, FPGAs, or the like. As examples of molds, there are molds for use in substrate processing such as imprint processing, or the like.

The pattern of the cured substance is used as is to serve as a configuring element of at least a portion of the above-described article, or is used temporarily as a composition mask. Composition masks are eliminated after etching or ion implantation and the like have been performed during the treatment process for the substrate.

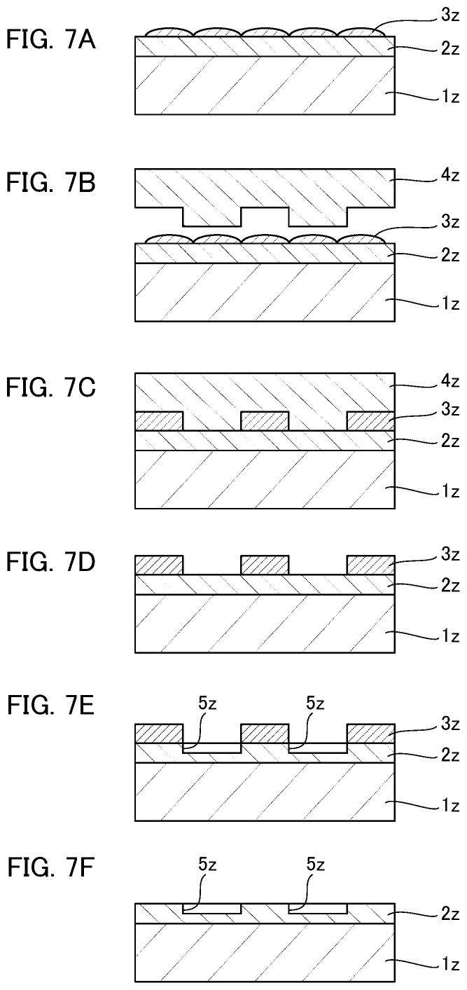

Next, the specific manufacturing method for an article will be explained in reference to FIG. 7. As is shown in FIG. 7A, a substrate 1z such as a silicone substate or the like on which a material to be treated 2z such as an insulator or the like has been formed on the surface is prepared, and next, a composition 3z is added to the surface of the material to be treated 2z using an ink jet method or the like. In this context, a state is shown in which the composition 3z, which takes the form of a plurality of droplets, has been added on top of the substrate 1z.

As is shown in FIG. 7B, a mold 4z is made to oppose the composition 3z on top of the substrate 1z such that the side of the mold 4z on which a protruding and receding pattern has been formed faces this. As is shown in FIG. 7C, the mold 4z is contacted with the substrate 1z, on which the composition 3z has been added, and pressure is applied (a contacting process). The composition 3Z fills the gaps between the mold 4z and the material to be treated 2z. When a light that serves as the energy for curing is transmitted through the mold 4z and is irradiated in this state, the composition 3z is cured (a curing process). At this time in the Present Embodiment, it becomes possible to irradiate the composition with light at an irradiation amount such that the optimal degree of photopolymerization is achieved based on spectral sensitivity characteristics that have been acquired within the apparatus.

As is shown in FIG. 7D, after the composition 3z has been cured, when the mold 4z and the substrate 1z are separated, a pattern of the cured substance of the composition 3z is formed on top of the substrate 1z (a pattern forming process, a formation process). This pattern of cured substance becomes a form in which the recessed portions of the mold 4z correspond to the protruding portions of the cured substance, and the protruding portions of the mold 4z correspond to the recessed portions of the cured substance. That is, it becomes such that the pattern of recessions and protrusions from the mold 4z is transferred to the composition 3z.

As is shown in FIG. 7E, when etching is performed where the pattern of the cured substance serves as an etching-resistant mask, from among the surface of the material to be treated 2z, the portions in which there is no cured substance, or in which the cured substance only thinly remains are eliminated, and these portions become grooves 5z. As is shown in FIG. 7F, when the pattern of the cured substance is eliminated, it is possible to obtain an article in which grooves 5z have been formed on the surface of the material to be treated 2z. In this context, although the pattern of the cured substance has been removed, this may also be used, for example, as a film for use in layer insulation that is included in a semiconductor element or the like, that is, as a configurational element of an article, without being removed after the treatment. Note that although an example has been explained in which a mold for use in transferring a circuit pattern on which a pattern of protrusions and recessions has been provided is used as the mold 4z, the mold 4z may also be a plane template having a plane unit that does not have a pattern of recessions and protrusions.

Above, preferred embodiments of the present invention have been described. However, the present invention is not limited to these embodiments, and various changes and modifications are possible within the scope of the gist thereof. In addition, the above-described embodiments may also be implemented by combining these embodiments.

In addition, a portion or the entirety of the control in each of the above-described embodiments may also be provided to the cleaning apparatus 100 and the imprint apparatus 200 or the like via a computer program that executes the functions of each of the above-described embodiments using a network or each type of storage medium. In addition, a computer (or a CPU, an MPU, or the like) in the cleaning apparatus 100, the imprint apparatus 200, or the like may also be made to read out and execute a program. In this case, the invention is configured by this program, and a storage medium on which this program has been stored.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2022-146977, Sep. 15, 2022, which is hereby incorporated by reference herein in its entirety.

What is claimed is:

1. A cleaning apparatus configured to clean an original plate used when forming a pattern in an imprint material on top of a substrate, the cleaning apparatus comprising:
an irradiating unit configured to release plasma onto a first side of the original plate; and
a heating unit configured to radiate heat onto a second side of the original plate and heat the original plate; wherein
the heating unit and the irradiating unit are disposed such that the original plate is interposed between the heating unit and the irradiating unit.

2. The cleaning apparatus according to claim 1, wherein the original plate has a pattern unit for forming the pattern in the imprint material, and the pattern unit forms the pattern on the first side of the original plate.

3. The cleaning apparatus according to claim 2, wherein the area of the heating unit is equal to or greater than the area of the pattern unit of the original plate.

4. The cleaning apparatus according to claim 1, wherein the original plate has a cavity unit, and the cavity unit is formed on the second side of the original plate.

5. The cleaning apparatus according to claim 4, wherein the outer circumference of the heating unit is smaller than the inner circumference of the cavity unit.

6. The cleaning apparatus according to claim 4, wherein the cleaning apparatus has a first drive unit configured to drive the heating unit in relation to the original plate.

7. The cleaning apparatus according to claim 6, wherein the cleaning apparatus further comprises a control unit that is configured to control the first drive unit,
wherein the control unit controls the first drive unit such that a surface of a side of the heating unit that releases the heat and the base of the cavity unit become a predetermined interval.

8. The cleaning apparatus according to claim 1, wherein the cleaning apparatus has a second drive unit that moves the irradiating unit in relation to the original plate.

9. The cleaning apparatus according to claim 1, wherein the cleaning apparatus has a third drive unit that moves the original plate in relation to the irradiating unit.

10. The cleaning apparatus according to claim 1, wherein the heating unit heats the original plate using far infrared light.

11. The cleaning apparatus according to claim 1, wherein the cleaning apparatus has a supply port that is configured to supply purge gas in the vicinity of the irradiating unit, and an exhaust port that is configured to expulse gas including the purge gas from its surroundings.

12. The cleaning apparatus according to claim 11, wherein the cleaning apparatus has a heating mechanism configured to heat at least one of a first gas for generating the plasma, a second gas comprising reaction substances, or the purge gas.

13. A cleaning method that cleans an original plate used when a pattern is formed in an imprint material on top of a substrate, wherein the cleaning method comprises:
a cleaning process in which the original plate is cleaned by an irradiating unit that is configured to release plasma onto a first side of the original plate; wherein
during the cleaning process, heat is radiated onto a second side of the original plate by a heating unit that has been disposed such that the original plate is interposed between the irradiating unit and the heating unit.

14. An imprint apparatus, wherein the imprint apparatus forms a pattern in an imprint material on top of a substrate using an original plate after the original plate has been cleaned using a cleaning apparatus, the cleaning apparatus comprising:
an irradiating unit that is configured to release plasma onto a first side of the original plate that is used when forming the pattern in the imprint material on top of the substrate; and
a heating unit that is configured to radiate heat onto a second side of the original plate and to heat the original plate; wherein
the heating unit and the irradiating unit are disposed such that the original plate is interposed between the irradiating unit and the heating unit.

15. A process for manufacturing an article, the process comprising:
a pattern forming process in which a pattern is formed on top of a substrate using an imprint apparatus that is configured to form the pattern in an imprint material on top of the substrate using an original plate;
a treatment process that treats the substrate on which the pattern has been formed during the pattern formation process; and
a process for manufacturing an article from the substrate that has been treated during the treatment process; wherein
the pattern forming process, the treatment process, and the process for manufacturing the article are executed after an original plate has been cleaning using a cleaning apparatus comprising:
an irradiating unit that is configured to release plasma onto a first side of the original plate that is used when forming the pattern in the imprint material on top of the substrate; and
a heating unit that is configured to radiate heat onto a second side of the original plate and to heat the original plate; wherein
the heating unit and the irradiating unit are disposed such that the original plate is interposed between the irradiating unit and the heating unit.
